(19) United States
(12) Patent Application Publication
(10) Pub. No.: US 2026/0006712 A1
(43) Pub. Date: Jan. 1, 2026

(54) PRINTED SUBSTRATE AND MOUNTED PRODUCT PRODUCTION METHOD

(71) Applicant: FANUC CORPORATION, Yamanashi (JP)

(72) Inventor: Makoto BEKKE, Yamanashi-ken (JP)

(21) Appl. No.: 18/880,648

(22) PCT Filed: Jul. 15, 2022
(86) PCT No.: PCT/JP2022/027858

§ 371 Date: Jan. 2, 2025

(51) Int. Cl. H05K 1/02; H05K 1/11

(52) U.S. Cl. CPC H05K 1/0201; H05K 1/117

(57) ABSTRACT

A printed substrate used in the mounting of a heat-dissipation member includes a first pad; a second pad connected to a portion of the periphery of the first pad; and a solder paste coated on the second pad. The solder paste has a protruding part that protrudes from the second pad towards the first pad through the connected portion of the first pad and the second pad. The protruding part extends to the inside of a terminal arrangement region of the first pad.

### TECHNICAL FIELD

The present invention relates to a printed wiring board (a printed substrate) and a method of manufacturing a mounted product (a mounted product production method).

### BACKGROUND ART

Electronic components requiring a relatively large drive power may be mounted on a printed wiring board. In this case, a heat dissipation member may be mounted on the printed wiring board in order to suppress heat generation due to electric power consumption of the electronic components. When a heat dissipation member of the like is mounted on a printed wiring board, solder is generally used.

JP 2014-212276 A discloses a printed wiring board in which solder paste is divided into a plurality of sections and applied to pads. The solder paste is divided into a plurality of sections by a grid of solder resist banks provided on the pads of the printed wiring board. The solder resist bank acts for an escaping route of voids generated in the molten solder, which is molten solder paste. Therefore, voids generated in the molten solder are reduced.

### SUMMARY OF THE INVENTION

However, when the solder paste is divided into a plurality of sections, the mounted area of the heat dissipation member mounted on the printed wiring board is reduced, and the heat dissipation performance is reduced, as compared with the case where the solder paste is not divided. Therefore, it has been proposed to suppress the voids without reducing the heat dissipation performance.

An object of the present invention is to solve the aforementioned problem.

A first aspect of the present invention is a printed wiring board used for mounting a heat dissipation member, including a first pad configured to mount the heat dissipation member, a second pad disposed around the first pad and connected to a part of a peripheral edge of the first pad, and a solder paste applied on the second pad, wherein the solder paste includes a protrusion protruding from the second pad to the first pad through a connecting portion between the first pad and the second pad, the protrusion extends to an inside of a terminal layout region of the first pad, which is a region where a terminal of the heat dissipation member is placed.

A second aspect of the present invention is a method of manufacturing a mounted product in which a heat dissipation member is mounted on a printed wiring board, the method including a melting step of melting a solder paste applied to the printed wiring board, wherein the printed wiring board includes a first pad, a second pad connected to a part of a peripheral edge of the first pad, and the solder paste applied on the second pad, the solder paste includes a protrusion to the first pad through a connecting portion between the first pad and the second pad, and the protrusion extends to an inside of a terminal layout region of the first pad, which is a region where a terminal of the heat dissipation member is placed, and in the melting step, a molten solder that is the solder paste which is melted, is moved from the second pad to the terminal layout region through the protrusion by a wetting force of the molten solder.

According to the aspect of the present invention, the voids can be suppressed without reducing the heat dissipation performance.

### BRIEF DESCRIPTION OF DRAWINGS

FIG. 1 is a top view of a printed wiring board according to an embodiment;

FIG. 2 is a cross-sectional view taken along line II-II of FIG. 1;

FIG. 3 is a flowchart illustrating a method of manufacturing a mounted product;

FIG. 4 is a top view illustrating the flow of molten solder;

FIG. 5 is a cross-sectional view taken along line V-V of FIG. 4;

FIG. 6 is a top view showing a printed wiring board according to exemplary modification 1;

FIG. 7 is a top view showing a printed wiring board according to exemplary modification 2; and

FIG. 8 is a top view showing a printed wiring board according to exemplary modification 3.

### DESCRIPTION OF THE INVENTION

### Embodiment

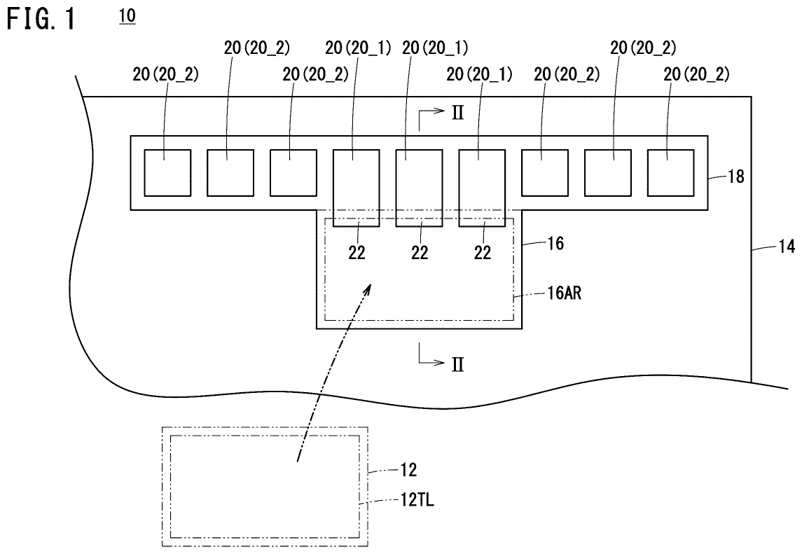

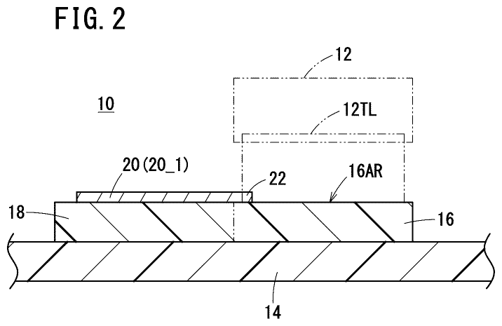

FIG. 1 is a top view of a printed wiring board 10 according to an embodiment. FIG. 2 is a cross-sectional view taken along line II-II of FIG. 1. The printed wiring board 10 is a printed wiring board on which the heat dissipation member 12 is not mounted. The printed wiring board 10 is used for mounting the heat dissipation member 12 (FIG. 2). The printed wiring board 10 includes a substrate 14, a first pad 16, a second pad 18, and solder pastes 20.

The first pad 16 is a metal foil for mounting the heat dissipation member 12. The first pad 16 has a terminal layout region 16AR. The terminal layout region 16AR is a region where a terminal (or a portion including terminals) 12TL of the heat dissipation member 12 is disposed. The terminal 12TL is a portion to be soldered and disposed on the bottom surface of the heat dissipation member 12. The terminal layout region 16AR may have the same size as the terminal 12TL or may be larger than the terminal 12TL of the heat dissipation member 12. FIGS. 1 and 2 show an example in which the terminal layout region 16AR is larger than the terminal 12TL of the heat dissipation member 12. In the case of FIGS. 1 and 2, the area of the first pad 16 is substantially equal to the bottom surface of the heat dissipation member 12.

The second pad 18 is a metal foil for applying the solder paste 20. Electronic components including the heat dissipation member 12 are not mounted on the second pad 18. The second pad 18 is connected to a part of the peripheral edge of the first pad 16. In this embodiment, the second pad 18 is connected to one side of the first pad 16 having a rectangular shape. The side of the first pad 16 to which the second pad 18 is connected may be one long side of the rectangular first pad 16. In the present embodiment, the second pad 18 is in the shape of a rod extending in one direction, and is disposed along the peripheral edge of the printed wiring board 10 (substrate 14).

The solder paste 20 is applied onto the second pad 18. The solder paste 20 includes a flux. The solder paste 20 may be referred to as cream solder.

In the present embodiment, the plurality of solder pastes (solder paste deposits) 20 are provided. Some of the plurality of solder pastes 20 each have a protrusion 22. The solder pastes 20 having the protrusions 22 may be referred to as first solder paste deposits 20_1. The first solder paste deposits 20_1 are disposed near a connecting portion between the first pad 16 and the second pad 18. The size of the first solder paste deposit 20_1 is larger than the size of the solder paste 20 having no protrusion 22. The solder pastes 20 having no protrusion 22 may be referred to as second solder paste deposits 20_2.

The protrusion 22 protrudes from the second pad 18 to the first pad 16 through the connecting portion between the first pad 16 and the second pad 18. The protrusion 22 extends to the inside of the terminal layout region 16AR of the first pad 16.

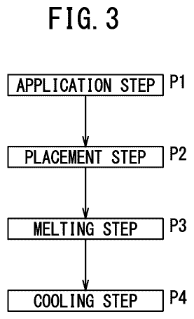

FIG. 3 is a flowchart illustrating a method of manufacturing a mounted product. The mounted product is the printed wiring board 10 on which at least the heat dissipation member 12 is mounted. The method of manufacturing the mounted product includes an application step P1, a placement step P2, a melting step P3, and a cooling step P4.

The application step P1 is a step of applying the solder paste 20 on the second pad 18. In the application step P1, for example, a solder printer is used. The solder printer applies a paste of solder that has been supplied on the metal mask, to the second pad 18 through holes in the metal mask using a squeegee, as the solder pastes 20.

The placement step P2 is a step of placing the terminal 12TL of the heat dissipation member 12 on the terminal layout region 16AR of the first pad 16. In this case, at least a part of each of the protrusions 22 is placed between the terminal 12TL of the heat dissipation member 12 and the terminal layout region 16AR of the first pad 16. The surface of each of the protrusions 22 facing the terminal layout region 16AR is in contact with the first pad 16. At least a portion of the surface of each of the protrusions 22 facing the terminal 12TL is in contact with the terminal 12TL.

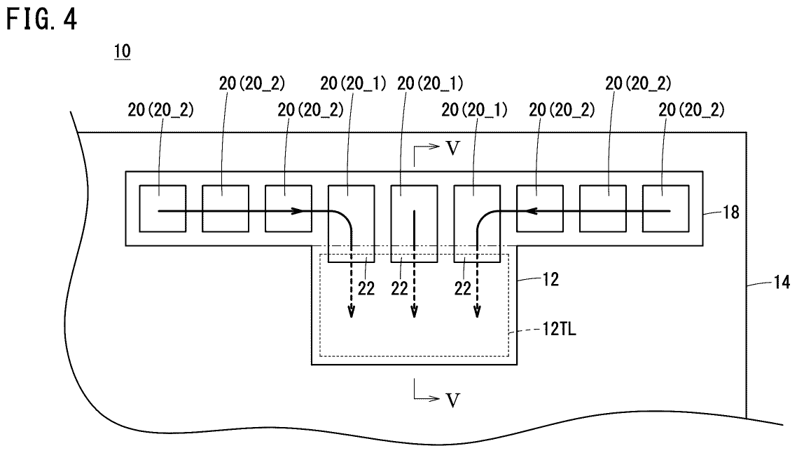

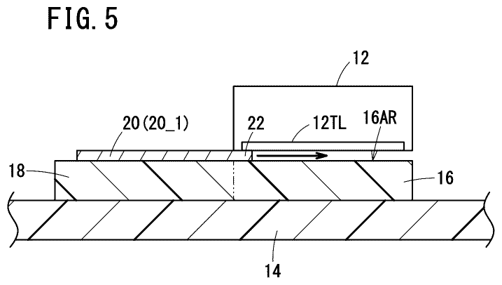

The melting step P3 is a step of melting the solder pastes 20 applied on the second pad 18. In the melting step P3, for example, a reflow apparatus is used. The reflow apparatus heats the solder pastes 20 to a predetermined temperature. The solder pastes 20 melt when heated to a predetermined temperature. The molten solder pastes 20 (molten solder) become wet and flow (see FIGS. 4 and 5). In this case, a first molten solder, as the molten first solder paste deposits 20_1, flows into the gap between the first pad 16 and the terminal 12TL of the heat dissipation member 12, starting from the protrusions 22 (as starting points) disposed between the terminal layout region 16AR of the first pad 16 and the terminal 12TL of the heat dissipation member 12. On the other hand, a second molten solder, as the molten second solder paste deposits 20_2, is wetted and spread to be fused with the first molten solder, and flows into the gap between the first pad 16 and the terminal 12TL of the heat dissipation member 12. In the case that a void is generated in the molten solder, the void cannot follow the flow of the molten solder and comes out of the molten solder.

In this way, in the melting step P3, the molten solder is moved from the second pad 18 to the terminal layout region 16AR of the first pad 16 through the protrusions 22 by the wetting force of the molten solder. Thus, even if the area of the terminal layout region 16AR is large, the molten solder in an undivided state can be placed in the gap between the first pad 16 and the terminal 12TL of the heat dissipation member 12. In addition, voids in the molten solder placed in the gap between the first pad 16 and the terminal 12TL of the heat dissipation member 12 can be reduced.

The cooling step P4 is a step of cooling the molten solder disposed in the gap between the first pad 16 and the terminal 12TL of the heat dissipation member 12. In the cooling step P4, for example, a reflow apparatus is used. The reflow apparatus cools the molten solder to a predetermined cooling temperature. The molten solder is hardened by cooling, and becomes hardened solder.

### Exemplary Modifications

The above-described embodiment may be modified in the following manner. In the following description, the description overlapping with the above embodiment will be appropriately omitted. In the following description, the same reference numerals are used for the same elements as those described in the above embodiments.

### (Exemplary Modification 1)

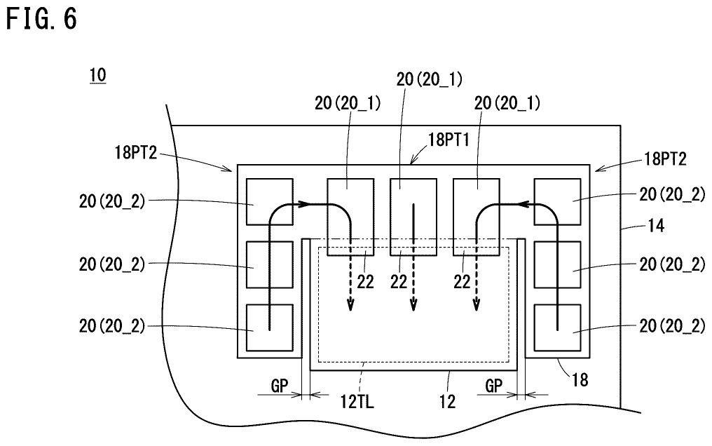

FIG. 6 is a top view showing a printed wiring board 10 according to exemplary modification 1. In the printed wiring board 10 according to the present modification, the shape of the second pad 18 is different from that of the above-described embodiment.

In the case of the present modification, the second pad 18 includes a central portion 18PT1 and two L-shaped portions 18PT2. The central portion 18PT1 is connected to one of the long sides of the rectangular first pad 16. The two L-shaped portions 18PT2 are disposed in line symmetry with respect to an imaginary line passing through the center of the central portion 18PT1. Each of the L-shaped portions 18PT2 has a gap GP between a portion extending along the short side of the rectangular first pad 16 and the first pad 16.

In the case of the present modification, the first solder paste deposits 20_1 are disposed in the central portion 18PT1 of the second pad 18. The second solder paste deposits 20_2 are disposed in either one of the two L-shaped portions 18PT2 of the second pad 18.

In the case of the present modification, in the melting step P3, the first molten solder as the molten first solder paste deposits 20_1 flows into the gap between the first pad 16 and the terminal 12TL of the heat dissipation member 12 from the protrusions 22 as starting points. The second molten solder as the molten second solder paste deposits 20_2 is wetted and spread to be fused with the first molten solder, and flows into the gap between the first pad 16 and the terminal 12TL of the heat dissipation member 12 from the L-shaped portion 18PT2 through the central portion 18PT1.

As described above, even in the case of the present modification, in the melting step P3, the molten solder is moved from the second pad 18 to the terminal layout region 16AR of the first pad 16 through the protrusions 22 by the wetting force of the molten solder. Therefore, the same effects and advantages as those of the embodiment can be obtained in the present modification.

### (Exemplary Modification 2)

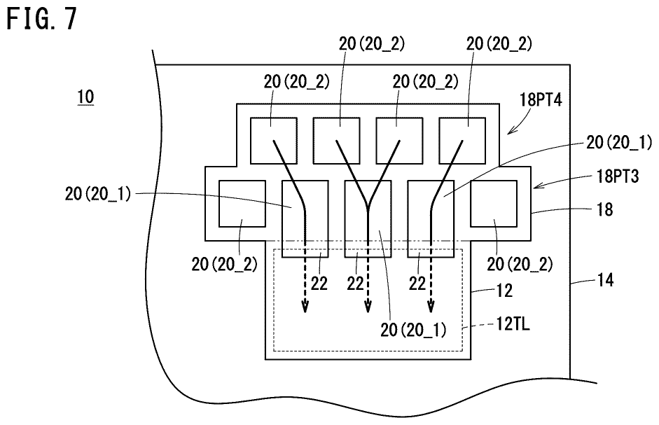

FIG. 7 is a top view showing a printed wiring board 10 according to exemplary modification 2. In the printed wiring board 10 according to the present modification, the shape of the second pad 18 is different from that of the above-described embodiment.

In the case of the present modification, the second pad 18 is formed in a “T” shape. The second pad 18 includes a base portion 18PT3 and a protruding end portion 18PT4. The base portion 18PT3 is a portion extending along the long side of the rectangular first pad 16, and is connected to one of the long sides of the first pad 16. The protruding end portion 18PT4 protrudes from a portion of the base portion 18PT3 opposite to the connecting portion of the base portion 18PT3 connected to the first pad 16.

In the case of the present modification, the first solder paste deposits 20_1 are disposed on the base portion 18PT3. The second solder paste deposits 20_2 are disposed at the protruding end portion 18PT4 and both ends of the base portion 18PT3. The second solder paste deposits 20_2 are arranged so as to surround the first solder paste deposits 20_1.

In the case of the present modification, in the melting step P3, the first molten solder as the molten first solder paste deposits 20_1 flows into the gap between the first pad 16 and the terminal 12TL of the heat dissipation member 12 from the protrusions 22 as starting points. The second molten solder as the molten second solder paste deposits 20_2 is wetted and spread to be fused with the first molten solder, and flows into the gap between the first pad 16 and the terminal 12TL of the heat dissipation member 12, from the protruding end portion 18PT4 and both ends of the base portion 18PT3.

As described above, even in the case of the present modification, in the melting step P3, the molten solder is moved from the second pad 18 to the terminal layout region 16AR of the first pad 16 through the protrusions 22 by the wetting force of the molten solder. Therefore, the same effects and advantages as those of the embodiment can be obtained in the present modification.

### (Exemplary Modification 3)

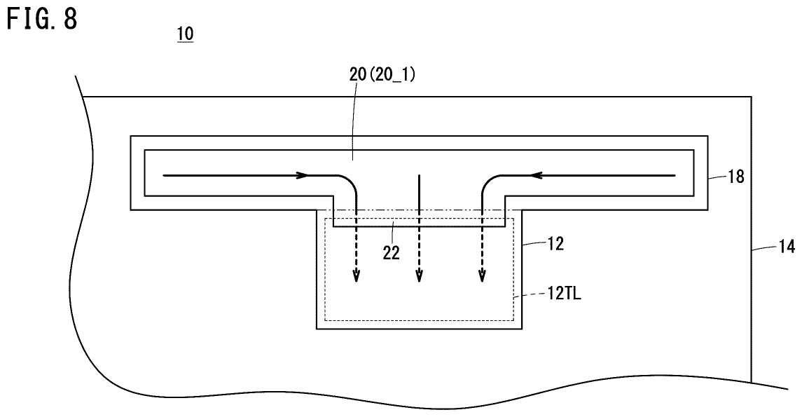

FIG. 8 is a top view showing a printed wiring board 10 according to exemplary modification 3. The printed wiring board 10 according to the present modification differs from the above embodiment in the size and shape of the solder paste 20.

In the case of the present modification, the single solder paste 20 is provided. The area of the single solder paste 20 is preferably the same as or close to the area of the terminal layout region 16AR of the first pad 16.

If a plurality of solder pastes 20 are provided as in the embodiment, the exemplary modification 1, or the exemplary modification 2, the total application area of the plurality of solder pastes 20 is preferably equal to or close to the area of the terminal layout region 16AR of the first pad 16.

The invention that can be grasped from the above embodiment and modifications are described below.

(1) The present invention is the printed wiring board (10) used for mounting the heat dissipation member (12), including the first pad (16) configured to mount the heat dissipation member, the second pad (18) disposed around the first pad and connected to the part of the peripheral edge of the first pad, and the solder paste (20) applied on the second pad, wherein the solder paste includes the protrusion (22) protruding from the second pad to the first pad through the connecting portion between the first pad and the second pad, the protrusion extends to the inside of the terminal layout region (16AR) of the first pad, which is the region where the terminal (12TL) of the heat dissipation member is placed.

In the printed wiring board of the present invention, the wetting force of the molten solder, which is a molten solder paste, can cause the molten solder to move from the second pad to the terminal layout region of the first pad with the protrusion as a starting point. In the case that the voids are generated in the molten solder, the voids cannot follow the movement of the molten solder and come out of the molten solder. Therefore, even if the area of the terminal layout region is large, the molten solder can be disposed between the terminal layout region and the terminal of the heat dissipation member in a non-divided state and in a state where the voids are reduced. In this way, according to the printed wiring board of the present invention, the voids can be suppressed without reducing the heat dissipation performance.

(2) In the printed wiring board of the present invention, the part of the second pad may be disposed along the peripheral edge of the printed wiring board. In accordance with this feature, it is possible to dispose the second pad while ensuring the wiring pattern.

(3) In the printed wiring board of the present invention, the second pad may have a rod shape extending in one direction. In accordance with this feature, it is possible to dispose the second pad along the peripheral edge of the printed wiring board. As a result, the second pad can be easily disposed while ensuring the wiring pattern.

(4) In the printed wiring board of the present invention, the second pad may include an L-shaped portion. In accordance with this feature, it is possible to dispose the second pad at the corner of the printed wiring board. As a result, the second pad can be easily disposed while ensuring the wiring pattern.

(5) The present invention is the method of manufacturing the mounted product in which the heat dissipation member is mounted on the printed wiring board, the method including the melting step (P3) of melting the solder paste applied to the printed wiring board, wherein the printed wiring board includes the first pad, the second pad connected to the part of the peripheral edge of the first pad, and the solder paste applied on the second pad, the solder paste includes the protrusion to the first pad through the connecting portion between the first pad and the second pad, and the protrusion extends to the inside of the terminal layout region of the first pad, which is the region where the terminal of the heat dissipation member is placed, and in the melting step, the molten solder that is the solder paste which is melted, is moved from the second pad to the terminal layout region through the protrusion by the wetting force of the molten solder.

In accordance with this feature, even if the area of the terminal layout region is large, the molten solder can be disposed between the terminal layout region and the terminal of the heat dissipation member in a non-divided state. The voids generated in the molten solder can be removed from the molten solder without allowing the voids to follow the movement of the molten solder. In this way, according to the method of manufacturing the mounted product of the present invention, the voids can be suppressed without reducing the heat dissipation performance.

(6) The method of manufacturing the mounted product of the present invention may further include the placement step (P2) of placing the terminal of the heat dissipation member on the terminal layout region before the melting step, wherein the surface of the protrusion facing the terminal of the heat dissipation member may be in contact with the terminal of the heat dissipation member. In accordance with this feature, the molten solder is made to move easily in the gap between the terminal of the heat dissipation member and the first pad due to the surface tension of the molten solder. Accordingly, the efficiency of movement of the molten solder between the terminal of the heat dissipation member and the first pad can be improved.

### REFERENCE SIGNS LIST

10: printed wiring board
12: heat dissipation member
12TL: terminal
14: substrate
16: first pad
16AR: terminal layout region
18: second pad
20: solder paste
20_1: first solder paste deposit
20_2: second solder paste deposit
22: protrusion

1. A printed wiring board used for mounting a heat dissipation member, comprising:
a first pad configured to mount the heat dissipation member;
a second pad disposed around the first pad and connected to a part of a peripheral edge of the first pad; and
a solder paste applied on the second pad,
wherein the solder paste includes a protrusion protruding from the second pad to the first pad through a connecting portion between the first pad and the second pad,
the protrusion extends to an inside of a terminal layout region of the first pad, which is a region where a terminal of the heat dissipation member is placed.

2. The printed wiring board according to claim 1, wherein a part of the second pad is disposed along a peripheral edge of the printed wiring board.

3. The printed wiring board according to claim 1, wherein the second pad has a rod shape extending in one direction.

4. The printed wiring board according to claim 1, wherein the second pad includes an L-shaped portion.

5. A method of manufacturing a mounted product in which a heat dissipation member is mounted on a printed wiring board, the method comprising a melting step of melting a solder paste applied to the printed wiring board,
wherein the printed wiring board includes a first pad, a second pad connected to a part of a peripheral edge of the first pad, and the solder paste applied on the second pad, the solder paste includes a protrusion to the first pad through a connecting portion between the first pad and the second pad, and the protrusion extends to an inside of a terminal layout region of the first pad, which is a region where a terminal of the heat dissipation member is placed, and
in the melting step, a molten solder that is the solder paste which is melted, is moved from the second pad to the terminal layout region through the protrusion by a wetting force of the molten solder.

6. The method of manufacturing the mounted product according to claim 5, further comprising a placement step of placing the terminal of the heat dissipation member on the terminal layout region before the melting step,
wherein a surface of the protrusion facing the terminal of the heat dissipation member is in contact with the terminal of the heat dissipation member.
